(19) United States
(12) Patent Application Publication
(10) Pub. No.: US 2026/0280440 A1
(43) Pub. Date: Sep. 17, 2026

(54) POWER CONVERTER

(71) Applicant: MITSUBISHI HEAVY INDUSTRIES, LTD., Tokyo (JP)

(72) Inventor: Tomoyuki MANABE, Tokyo (JP)

(73) Assignee: MITSUBISHI HEAVY INDUSTRIES, LTD., Tokyo (JP)

(21) Appl. No.: 19/166,796

(22) PCT Filed: Nov. 9, 2023
(86) PCT No.: PCT/JP2023/040423

§ 371 Date: Sep. 18, 2025

(30) Foreign Application Priority Data
Mar. 24, 2023 (JP) 2023-048035

(51) Int. Cl. H02M 7/00; H05K 7/20

(52) U.S. Cl. CPC H02M 7/003; H05K 7/2089

(57) ABSTRACT

This power converter is provided with: a base plate having a main surface and a back surface that faces the opposite way from the main surface; a circuit board (2) having an insulating plate (20) provided on the main surface and a circuit pattern (21) formed on the insulating plate; a first element group (50a) and a second element group (50b) electrically connected to the circuit pattern and including a plurality of semiconductor elements for converting the input power; and cooling parts provided on the back surface and transmitting cold energy of a refrigerant flowing inside in the first direction (D1) to the base plate. The first element group is disposed further apart on the downstream side in the first direction than the second element group. The plurality of semiconductor elements of the first element group are disposed side by side at intervals in a second direction (D2) intersecting with the first direction. The plurality of semiconductor elements of the second element group are disposed side by side at intervals in the second direction. An interval (L1) between the two adjacent semiconductor elements in the first element group is wider than an interval (L2) between the two adjacent semiconductor elements in the second element group.

### DESCRIPTION

### Technical Field

The present disclosure relates to a power converter.

This application claims the priority of Japanese Patent Application No. 2023-048035 filed in Japan on Mar. 24, 2023, the content of which is incorporated herein by reference.

### Background Art

PTL 1 discloses a cooling structure of power modules in which a plurality of the power modules are provided to be aligned in a constant direction on a surface of a liquid-cooled heat sink, and a water channel of the liquid-cooled heat sink through which a refrigerant flows extends in the constant direction.

### CITATION LIST

### Patent Literature

[PTL 1] Japanese Unexamined Patent Application Publication No. 2008-41806

### SUMMARY OF INVENTION

### Technical Problem

Meanwhile, in a power converter using a power semiconductor element, a plurality of power semiconductor elements may be aligned along a flow direction of the refrigerant in some cases. In this case, the power semiconductor element disposed on a downstream side in the flow direction of the refrigerant is cooled by cold energy of the refrigerant that removes heat of the power semiconductor element disposed on an upstream side. Therefore, there is a problem in that cooling efficiency of the refrigerant decreases.

The present disclosure has been made to solve the above-described problems, and an object of the present disclosure is to provide a power converter capable of suppressing a decrease in cooling efficiency of a refrigerant.

### Solution to Problem

According to the present disclosure, in order to solve the above-described problems, there is provided a power converter including a base plate having a main surface and a back surface facing a side opposite to the main surface, a circuit board having an insulating plate provided on the main surface and a circuit pattern formed on the insulating plate, a power conversion unit having a first element group and a second element group, each including a plurality of power semiconductor elements electrically connected to the circuit pattern and converting input power, and cooling parts provided on the back surface and transmitting cold energy of a refrigerant flowing in a first direction inside the cooling parts to the base plate. The first element group is disposed to be separated from the second element group on a downstream side in the first direction. The plurality of power semiconductor elements included in the first element group are aligned at an interval from each other in a second direction intersecting with the first direction. The plurality of power semiconductor elements included in the second element group are aligned at an interval from each other in the second direction. An interval between two adjacent power semiconductor elements in the first element group is wider than an interval between two adjacent power semiconductor elements in the second element group.

According to the present disclosure, there is provided a power converter including a base plate having a main surface and a back surface facing a side opposite to the main surface, a circuit board having an insulating plate provided on the main surface and a circuit pattern formed on the insulating plate, a power conversion unit having a first power semiconductor element and a second power semiconductor element which are electrically connected to the circuit pattern and which convert input power, and cooling parts provided on the back surface and transmitting cold energy of a refrigerant flowing in a first direction inside the cooling parts to the base plate. The first power semiconductor element is disposed to be separated from the second power semiconductor element on a downstream side in the first direction. The cooling parts have a base portion coming into contact with the back surface, and a plurality of fins extending from the base portion to a side opposite to the base plate and coming into contact with the refrigerant. The plurality of fins are disposed at an interval from each other along the first direction and a second direction intersecting with the first direction. An interval between two adjacent fins becomes narrower toward the downstream side in the first direction.

### Advantageous Effects of Invention

According to the present disclosure, it is possible to provide a power converter capable of suppressing a decrease in cooling efficiency of a refrigerant.

### BRIEF DESCRIPTION OF DRAWINGS

FIG. 1 is a perspective view of a power converter according to a first embodiment of the present disclosure.

FIG. 2 is a view for describing a power conversion unit according to the first embodiment of the present disclosure.

FIG. 3 is a view for describing a power conversion unit according to a second embodiment of the present disclosure.

FIG. 4 is a view for describing a fin of cooling parts according to a third embodiment of the present disclosure.

### DESCRIPTION OF EMBODIMENTS

Hereinafter, a power converter according to an embodiment of the present disclosure will be described with reference to the accompanying drawings.

### First Embodiment of Power Converter

For example, the power converter is a device that converts direct current power into three-phase alternating current power or the like. For example, examples of the power converter include an inverter used in a system of a power plant or the like, and an inverter used for driving an alternating current rotary electric machine (motor) of an electric vehicle or the like. The power converter described in the present embodiment is a 2-in-1 module configured to convert input direct current power and to output any one of three-phase (U-phase, V-phase, and W-phase) alternating current power.

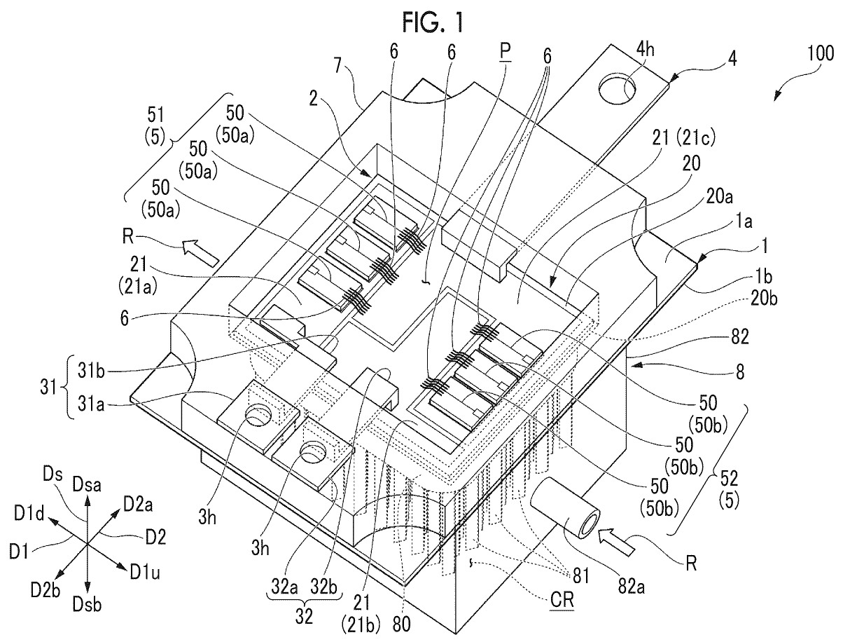

As shown in FIG. 1, a power converter 100 includes a base plate 1, a circuit board 2, a first conductor 3, a second conductor 4, a power conversion unit 5, a bonding wire 6, a resin case 7, and cooling parts 8.

### (Base Plate)

The base plate 1 is a member to which elements forming the power converter 100 are attached. The base plate 1 has a flat plate shape. For example, the base plate 1 is formed of a metallic material containing copper. A material for forming the base plate 1 is not limited to copper, and may be a metallic material containing aluminum or the like. The base plate 1 has a main surface la and a back surface 1b facing a side opposite to the main surface 1a. That is, the main surface la and the back surface 1b are in a back-to-back relationship. Each of the above-described elements is attached (fixed) to the base plate 1 to be laminated on the main surface 1a and the back surface 1b. Hereinafter, for convenience of description, a direction in which the main surface la and the back surface 1b of the base plate 1 are aligned will be referred to as a “lamination direction Ds”. In addition, a side away from the main surface la in the lamination direction Ds will be referred to as an “upper side Dsa”, and a side opposite to the upper side Dsa (side away from the back surface 1b in the lamination direction Ds) will be referred to as a “lower side Dsb”.

### (Circuit Board)

The circuit board 2 converts power (voltage) input from an outside. The circuit board 2 is provided in the base plate 1 from the upper side Dsa. The circuit board 2 has an insulating plate 20 and a circuit pattern 21.

### (Insulating Plate)

The insulating plate 20 is provided on the main surface la of the base plate 1. The insulating plate 20 has a flat plate shape. For example, the insulating plate 20 is formed of an insulating material containing ceramic. A material for forming the insulating plate 20 is not limited to ceramic, and, for example, paper phenol, paper epoxy, glass composite, glass epoxy, glass polyimide, fluororesin, or the like may be adopted. The insulating plate 20 has a first surface 20a facing the upper side Dsa and a second surface 20b facing the lower side Dsb. That is, the first surface 20a and the second surface 20b are in a back-to-back relationship. A pattern (not shown) of a copper foil or the like is formed on one surface of the second surface 20b. The pattern formed on the second surface 20b is connected to a central portion in the main surface 1a of the base plate 1 via a weld material (not shown) or the like. In this manner, the insulating plate 20 is fixed to the main surface 1a.

### (Circuit Pattern)

The circuit pattern 21 is a pattern of the copper foil or the like formed on the first surface 20a of the insulating plate 20. The circuit pattern 21 extends in a planar shape on the first surface 20a. For example, the circuit pattern 21 is fixed to the first surface 20a by joining or the like, and thereafter, is formed by etching or the like. In the present embodiment, a plurality of the circuit patterns 21 are independently disposed on the first surface 20a. The plurality of circuit patterns 21 are disposed adjacent to each other with a gap in a direction in which the insulating plate 20 extends. In the present specification, a case where three circuit patterns 21 are disposed on the first surface 20a will be described as an example. Hereinafter, for convenience of description, the three circuit patterns 21 will be referred to as a “first pattern 21a”, a “second pattern 21b”, and a “third pattern 21c”.

The first pattern 21a and the second pattern 21b are current paths for exchanging an input and an output of direct current power (direct current) with the outside of the circuit board 2, and correspond to an inlet portion or an outlet portion in a loop between PNs formed by the plurality of circuit patterns 21. In the present embodiment, the first pattern 21a is a current path on a positive electrode side (P side) in the plurality of circuit patterns 21, and the second pattern 21b is a current path on a negative electrode side (N side) in the plurality of circuit patterns 21.

Hereinafter, for convenience of description, a direction in which the first pattern 21a and the second pattern 21b are adjacent to each other will be referred to as a “first direction D1”. In addition, a direction intersecting with the first direction D1 will be referred to as a “second direction D2”. The second direction D2 in the present embodiment is a direction orthogonal to the first direction D1. In addition, one side of both sides in the second direction D2 will be simply referred to as “one side D2a”, and a side opposite to the one side D2a will be referred to as “the other side D2b”. The one side D2a and the other side D2b in the second direction D2 which are shown in the drawing may be reversely determined. In addition, the lamination direction Ds is a direction intersecting with each of the first direction D1 and the second direction D2. The lamination direction Ds in the present embodiment is orthogonal to each of the first direction D1 and the second direction D2.

The third pattern 21c is a current path for exchanging an input and an output of alternating current power (alternating current) with the outside of the circuit board 2. The third pattern 21c is adjacent to the first pattern 21a in the first direction D1, and is adjacent to the second pattern 21b in the second direction D2.

### (First Conductor)

The first conductor 3 is a current path for exchanging direct current between the circuit pattern 21 and a device (not shown) disposed outside the circuit board 2. Therefore, the first conductor 3 is electrically connected to the device. For example, examples of the device include a capacitor. For example, the first conductor 3 is formed of a metallic material containing copper. A material for forming the first conductor 3 is not limited to copper, and may be a metallic material containing aluminum or the like. The first conductor 3 includes a P bus bar 31 and an N bus bar 32.

### (P Bus Bar)

The P bus bar 31 is a portion corresponding to a positive electrode in the power converter 100, and is electrically connected to the first pattern 21a. The P bus bar 31 has a terminal portion 31a and a connecting portion 31b. The terminal portion 31a is disposed on the upper side Dsa with respect to the circuit board 2, and is an inlet portion of the current (direct current) flowing through the first conductor 3. The terminal portion 31a is formed in a flat plate shape. A hole portion 3h (for example, a hole for bolt fastening) for connecting a bus bar or the like connected to the device is formed in a central portion of the terminal portion 31a. The connecting portion 31b is provided integrally with the terminal portion 31a from the lower side Dsb. The connecting portion 31b electrically connects the terminal portion 31a and the first pattern 21a. That is, the current (direct current) flowing from the outside to the terminal portion 31a flows toward the first pattern 21a through the connecting portion 31b.

### (N Bus Bar)

The N bus bar 32 is a portion corresponding to a negative electrode in the power converter 100, and is electrically connected to the second pattern 21b. The N bus bar 32 has a terminal portion 32a and a connecting portion 32b. The terminal portion 32a is disposed on the upper side Dsa with respect to the circuit board 2, and is an outlet portion of the current (direct current) flowing through the first conductor 3. The terminal portion 32a is formed in a flat plate shape. In addition, hole portions 3h and 4h (for example, holes for bolt fastening) for connecting a bus bar or the like connected to the device are formed in a central portion of the terminal portion 32a. The terminal portion 32a of the N bus bar 32 in the present embodiment has the same shape as the terminal portion 31a of the P bus bar 31, and is aligned with the terminal portion 31a of the P bus bar 31 in the first direction D1. The connecting portion 32b is provided integrally with the terminal portion 32a from the lower side Dsb. The connecting portion 32b electrically connects the terminal portion 32a and the second pattern 21b. That is, the current (direct current) flowing through the second pattern 21b flows toward the terminal portion 32a through the connecting portion 32b.

### (Second Conductor)

The second conductor 4 is a current path (bus bar) for exchanging the alternating current with a load (not shown) of an alternating current rotary electric machine or the like disposed outside the circuit pattern 21 and the circuit board 2. For example, the second conductor 4 is formed of a metallic material containing copper. A material for forming the second conductor 4 is not limited to copper, and may be a metallic material containing aluminum or the like. One end portion in the second conductor 4 is electrically connected to the third pattern 21c, and the other end portion in the second conductor 4 extends outward of the power converter 100. A hole portion 4h for connecting an electric wire or the like connected to the load is formed in the other end portion of the second conductor 4.

### (Power Conversion Unit and Bonding Wire)

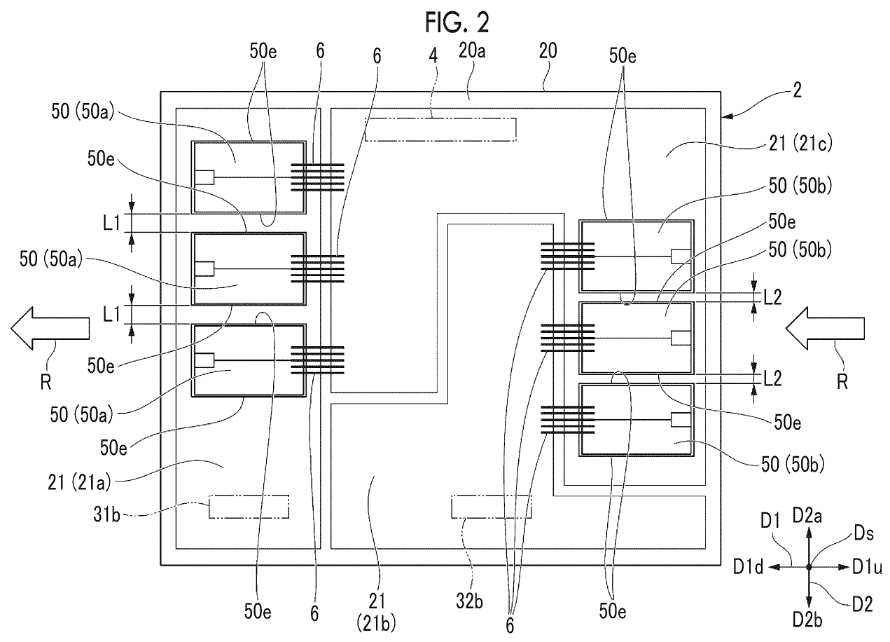

The power conversion unit 5 is an electronic component that converts the current flowing through the circuit pattern 21. In the present embodiment, the power conversion unit 5 is an assembly of circuit elements that convert a direct current voltage applied to the circuit pattern 21 into an alternating current voltage or convert an alternating current voltage applied to the circuit pattern 21 into a direct current voltage by using a switching operation. As shown in FIGS. 1 and 2, the power conversion unit 5 includes a first element group 51 and a second element group 52.

### (First Element Group)

The first element group 51 includes a plurality of power semiconductor elements 50. In the present embodiment, the first element group 51 includes three power semiconductor elements 50. The first element group 51 may include two, four, or more power semiconductor elements 50.

The power semiconductor element 50 converts power by performing a switching operation of turning on and off the voltage and the current. For example, the power semiconductor element 50 described below is a switching element such as a MOSFET or an IGBT. The power semiconductor element 50 in the present embodiment is a MOSFET. Each power semiconductor element 50 included in the first element group 51 is electrically connected to the first pattern 21a to convert the input direct current power into the alternating current power. Each power semiconductor element 50 has a rectangular shape having a long side portion extending in the first direction D1 and a short side portion extending in the second direction D2, when viewed from the upper side Dsa. Hereinafter, for convenience of description, the power semiconductor element 50 included in the first element group 51 may be referred to as a “first power semiconductor element 50a”.

The first power semiconductor element 50a has an input surface facing the lower side Dsb and having a terminal into which the current flowing through the circuit pattern 21 is input, and an output surface facing the upper side Dsa and having a terminal through which the converted current is output (reference numerals of the input surface and the output surface are omitted). For example, the input surface of the first power semiconductor element 50a is connected to the first pattern 21a via a weld material or the like. One end of the bonding wire 6 is connected to the output surface of the first power semiconductor element 50a. The other end of the bonding wire 6 is connected to the third pattern 21c. In the present embodiment, a plurality of (five in the example in the drawing) bonding wires 6 are connected to each of the first power semiconductor elements 50a. The bonding wire 6 is connected to the power semiconductor element 50 and the circuit pattern 21 by wire bonding. For example, the bonding wire 6 is formed of a metallic material containing aluminum.

Therefore, the current (alternating current) converted by the three first power semiconductor elements 50a flows to the third pattern 21c through the bonding wire 6. The output surface of the first power semiconductor element 50a and the third pattern 21c may be electrically connected by a lead frame or the like instead of the bonding wire 6.

The three first power semiconductor elements 50a are aligned at a predetermined interval (L1 shown in FIG. 2) in the second direction D2. In the present embodiment, the three first power semiconductor elements 50a are disposed on the first pattern 21a at an equal interval in the second direction D2. The “interval” referred to herein means an interval defined by a side edge portion 50e (corresponding to the long side portion) facing the second direction D2 of each of the first power semiconductor elements 50a between two adjacent first power semiconductor elements 50a.

### (Second Element Group)

The second element group 52 includes a plurality of power semiconductor elements 50. In the present embodiment, the second element group 52 includes the same number of the power semiconductor elements 50 as the first element group 51. The second element group 52 may include a number of power semiconductor elements 50 which is different from the number of the first element group 51, and may include two, four, or more power semiconductor elements 50. Hereinafter, for convenience of description, the power semiconductor element 50 included in the second element group 52 may be referred to as a “second power semiconductor element 50b”.

Each of the second power semiconductor elements 50b is electrically connected to the third pattern 21c to convert the input alternating current power into the direct current power. As shown in FIGS. 1 and 2, the second element group 52 and the first element group 51 are disposed to be separated from each other in the first direction D1.

Each of the second power semiconductor elements 50b has an input surface facing the lower side Dsb and having a terminal for inputting the current flowing through the circuit pattern 21, and an output surface facing the upper side Dsa and having a terminal for outputting the converted current (reference numerals of the input surface and the output surface are omitted). For example, the input surface of the second power semiconductor element 50b is connected to the third pattern 21c via a weld material. One end of the bonding wire 6 is connected to the output surface of the second power semiconductor element 50b. The other end of the bonding wire 6 is connected to the second pattern 21b. In the present embodiment, a plurality of (five as an example in the drawing) bonding wires 6 are connected to each of the second power semiconductor elements 50b.

Therefore, the current (alternating current) converted by three second power semiconductor elements 50b flows to the second pattern 21b through the bonding wire 6. The output surface of the second power semiconductor element 50b and the second pattern 21b may be electrically connected to each other by a lead frame or the like instead of the bonding wire 6.

The three second power semiconductor elements 50b are aligned at a predetermined interval (L2 shown in FIG. 2) in the second direction D2. In the present embodiment, the three second power semiconductor elements 50b are disposed at an equal interval in the second direction D2. The “interval” referred to herein means an interval defined by the side edge portion 50e (corresponding to the long side portion) facing the second direction D2 of each of the second power semiconductor elements 50b between two adjacent second power semiconductor elements 50b.

Here, an interval (L1) between the two adjacent first power semiconductor elements 50a in the first element group 51 is larger than an interval (L2) between the two adjacent second power semiconductor elements 50b in the second element group 52 (L1>L2).

In addition, the center position of the first element group 51 is shifted to the one side D2a in the second direction D2 with respect to the center position of the second element group 52. For example, the “center position” means a position that bisects a distance between a side edge portion 50e on the one side D2a of the power semiconductor element 50 disposed furthest on the one side D2a and a side edge portion 50e on the other side D2b of the power semiconductor element 50 disposed furthest on the other side D2b, in the plurality of power semiconductor elements 50 aligned in the second direction D2 in the first element group 51 and the second element group 52.

### (Resin Case)

As shown in FIG. 1, the resin case 7 is fixed to the main surface la of the base plate 1. For example, the resin case 7 covers a portion of the first conductor 3 and a portion of the second conductor 4 from the outside, and surrounds the circuit board 2 from the outside in a direction in which the base plate 1 extends. That is, the resin case 7 forms a case that surrounds the circuit board 2 from a periphery in a direction along the main surface 1a of the base plate 1 (direction along the first direction D1 and the second direction D2). For example, the resin case 7 is formed of a synthetic resin material such as polyphenylene sulfide (PPS). A material for forming the resin case 7 is not limited to PPS.

The resin case 7 defines a space in which the circuit board 2 is accommodated together with the main surface la of the base plate 1. In the present embodiment, the space will be referred to as a “potting space P”. For example, the potting space P is filled with a liquid potting material (potted) from the outside in a manufacturing process of the power converter 100. The potting material used for filling seals each member exposed inside the potting space P. The potting material filling the potting space P is cured over a predetermined time, and electrically insulates each member disposed in the potting space P and the outside of the potting space P. For example, a synthetic resin material such as a silicone gel or an epoxy resin can be adopted as the potting material in the present embodiment. In addition, a synthetic resin material other than a silicone gel or an epoxy resin may be adopted as the potting material.

### (Cooling Parts)

The cooling parts 8 remove heat generated from the power semiconductor element 50 by using a liquid-state refrigerant (hereinafter, referred to as a “liquid coolant R”) supplied from the outside. The cooling parts 8 are disposed on the lower side Dsb with respect to the base plate 1. In the present embodiment, the cooling parts 8 are provided on the back surface 1b of the base plate 1. The cooling parts 8 have a base portion 80, a fin 81, a cooling case 82, a refrigerant inlet 82a, and a refrigerant outlet (not shown for convenience of the drawing).

The base portion 80 has a plate shape having a pair of surfaces in a back-to-back relationship in the lamination direction Ds when attached to the base plate 1, and one surface facing the upper side Dsa is fixed to the back surface 1b of the base plate 1 via a weld material or the like. For example, the base portion 80 is formed of a metallic material containing aluminum. A material for forming the base portion 80 is not limited to aluminum, and may be formed of a metallic material containing copper or the like, for example. In addition, for example, the weld material used for welding the members to each other can adopt solder or a sintering material (powder of metal or the like).

The fin 81 is a heat dissipating member that protrudes integrally with the base portion 80 toward the lower side Dsb from a surface facing the lower side Dsb of the pair of surfaces of the base portion 80. Each of the fins 81 has a columnar shape extending in the lamination direction Ds. A plurality of the fins 81 are disposed at an interval in a direction in which the base portion 80 extends. In the present embodiment, the fins 81 adjacent to each other in the first direction D1 or the second direction D2 are disposed at an equal interval, for example. The fins 81 are formed of the same material as the material for forming the base portion 80.

For example, the cooling case 82 is fixed to the back surface 1b of the base plate 1 to surround the base portion 80 and the fins 81 from the outside. The cooling case 82 surrounds the base portion 80 and the fins 81 from the outside to form, together with the base portion 80 and the fins 81, a flow path through which the liquid coolant R flows. In the present embodiment, the flow path will be referred to as a “coolant flow path CR”.

The refrigerant inlet 82a is provided in the cooling case 82. Specifically, the refrigerant inlet 82a is provided in the cooling case 82 at a position on one side (upstream side D1u described above) in the first direction D1 with respect to the circuit board 2. The refrigerant inlet 82a is an opening portion of the coolant flow path CR for causing the liquid coolant R fed from a refrigerant supply device (not shown) or the like disposed outside the power converter 100 to flow into the coolant flow path CR. For example, water or the like is adopted as the liquid coolant R in the present embodiment. In addition, a liquid other than water may be adopted as the liquid coolant R. The liquid coolant R flowing into the coolant flow path CR from the refrigerant inlet 82a flows in the first direction D1. That is, the first direction D1 in the present embodiment coincides with a flow direction of the liquid coolant R. Therefore, the cooling parts 8 in the present embodiment use the fins 81 and the base portion 80 to transmit cold energy of the liquid coolant R flowing in the first direction D1 inside the cooling parts 8 to the base plate 1.

The refrigerant outlet (not shown) is provided on a side opposite to the refrigerant inlet 82a in the cooling case 82. Specifically, the refrigerant outlet is provided in the cooling case 82 at a position on the other side (downstream side D1d described above) in the first direction D1 with respect to the circuit board 2. The refrigerant outlet is an opening portion of the coolant flow path CR for returning the liquid coolant R completely flowing through the coolant flow path CR in the first direction D1 to the refrigerant supply device.

Hereinafter, a side to which the liquid coolant R flows in the first direction D1 (side on which the refrigerant inlet 82a is disposed in the cooling case 82) will be referred to as an “upstream side D1u”, and a side from which the liquid coolant R flows away in the first direction D1 (side on which the refrigerant outlet is disposed in the cooling case 82) will be referred to as a “downstream side D1d”. Therefore, as shown in FIGS. 1 and 2, the first element group 51 connected to the circuit pattern 21 of the circuit board 2 is disposed to be separated to the downstream side D1d in the first direction D1 with respect to the second element group 52.

### (Operational Effects)

The liquid coolant R flowing into the coolant flow path CR through the refrigerant inlet 82a comes into contact with each of the fins 81 and the base portion 80 in a process of flowing in the first direction D1. In this manner, the liquid coolant R exchanges heat with the fin 81 and the base portion 80. In other words, the liquid coolant R flowing through the coolant flow path CR transmits cold energy to the fin 81 and the base portion 80. The cold energy transmitted to the fin 81 is conducted toward the upper side Dsa through the base portion 80, the base plate 1, and the circuit board 2, in this order, and removes the heat of (cools) the plurality of power semiconductor elements 50 connected to the circuit pattern 21 of the circuit board 2. The liquid coolant R whose heat is actively removed from the plurality of second power semiconductor elements 50b (second element group 52) aligned in the second direction D2 in the liquid coolant R flowing through the coolant flow path CR on the lower side Dsb with respect to the base plate 1 flows to the downstream side D1d in the first direction D1 (flow direction of the liquid coolant R) while maintaining a heat distribution in the second direction D2.

In the above-described configuration, the interval between the two adjacent first power semiconductor elements 50a in the first element group 51 disposed on the downstream side D1d with respect to the second element group 52 is wider than the interval between the two adjacent second power semiconductor elements 50b in the second element group 52. In this manner, when the heat distribution in the second direction D2 of the liquid coolant R heated by the plurality of second power semiconductor elements 50b aligned in the second direction D2 is considered, heat removal of the plurality of first power semiconductor elements 50a is suppressed by the liquid coolant R having a relatively high temperature in the vicinity of a peak in the heat distribution. In other words, a probability increases in removing the heat of the plurality of first power semiconductor elements 50a by the liquid coolant R having a relatively low temperature (portion relatively close to a valley in the heat distribution) in the above-described heat distribution. Therefore, compared to when the interval between the two adjacent first power semiconductor elements 50a is the same as (or narrower than the interval between the two adjacent second power semiconductor elements 50b) the interval between the two adjacent second power semiconductor elements 50b, the liquid coolant R flowing to the downstream side D1d with respect to the second element group 52 inside the cooling parts 8 (coolant flow path CR) easily and effectively transmits the cold energy to each of the power semiconductor elements 50 included in the first element group 51. That is, the power semiconductor element 50 included in the first element group 51 can be further cooled. Therefore, a decrease in cooling efficiency of the liquid coolant R can be suppressed. As a result, an output of the power converter 100 can be improved.

In addition, in the above-described configuration, the center position of the first element group 51 is shifted to the one side D2a in the second direction D2 with respect to the center position of the second element group 52. Therefore, when the above-described heat distribution is considered, the probability increases in removing the heat of the first power semiconductor element 50a by the relatively low-temperature liquid coolant R flowing in the first direction D1 on the one side D2a in the liquid coolant R flowing to the downstream side D1d with respect to the second element group 52 in the coolant flow path CR. Therefore, the cold energy of the liquid coolant R is more easily and effectively transmitted to each of the power semiconductor elements 50 included in the first element group 51.

In addition, in the above-described configuration, the second element group 52 includes the same number of power semiconductor elements 50 as the first element group 51, and the plurality of power semiconductor elements 50 included in the second element group 52 are disposed at an equal interval in the second direction D2. In this manner, when the above-described heat distribution is considered, a shape of the heat distribution is close to a line-symmetrical shape in the second direction D2. As a result, the above-described operation can be realized with higher accuracy.

### Second Embodiment of Power Converter

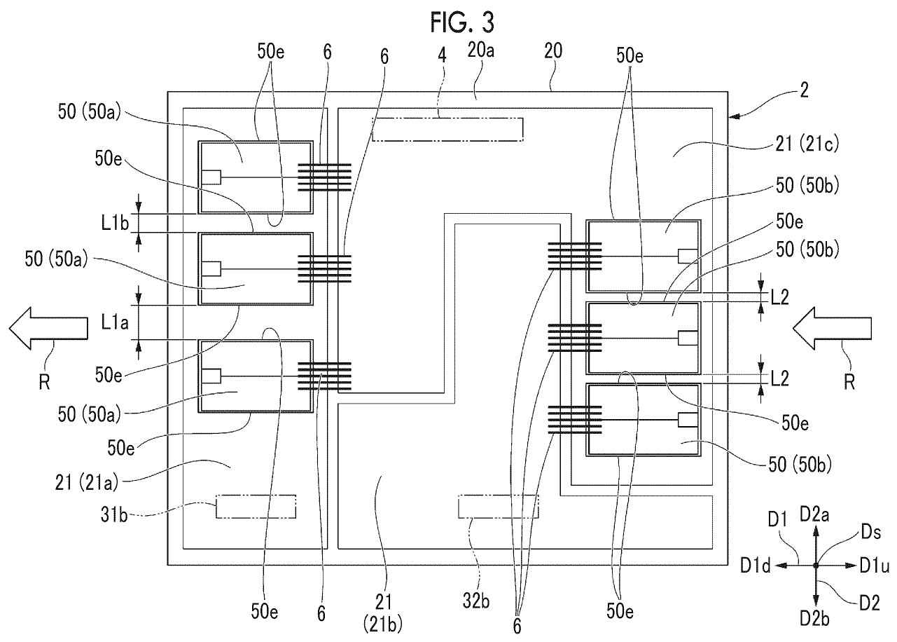

Next, a second embodiment of the power converter 100 will be described with reference to FIG. 3. In the second embodiment described below, the same reference numerals will be assigned to the configurations common to those in the first embodiment described above in the drawings, and description thereof will be omitted. In the present embodiment, a method for forming an interval between the two adjacent first power semiconductor elements 50a in the first element group 51 is different from that in the first embodiment.

In the present embodiment, an interval (L1a and L1b shown in FIG. 3) between the two adjacent first power semiconductor elements 50a in the first element group 51 is wider than an interval (L2 shown in FIG. 3) between the two adjacent second power semiconductor elements 50b in the second element group 52. In addition, the center position of the first element group 51 is shifted to the one side D2a in the second direction D2 with respect to the center position of the second element group 52.

Furthermore, the interval between the two adjacent first power semiconductor elements 50a in the first element group 51 becomes narrower toward the one side D2a in the second direction D2. That is, the interval (L1b) between the first power semiconductor element 50a disposed on the one side D2a and the first power semiconductor element 50a disposed in the center in the three first power semiconductor elements 50a aligned in the second direction D2 in the first element group 51 is narrower than the interval (L1a) between the first power semiconductor element 50a disposed on the other side D2b and the first power semiconductor element 50a disposed in the center (L1b<L1a).

### (Operational Effects)

According to the above-described configuration, while the operation described in the first embodiment is realized, it is possible to suppress an increase in a temperature difference between the three first power semiconductor elements 50a cooled by the liquid coolant R. That is, it is possible to suppress concentration of the heat on some of the first power semiconductor elements 50a. As a result, an output of the power converter 100 can be stabilized. In addition, while the above-described operation is realized, it is possible to suppress an increase in a space occupied by the first element group 51 on the circuit pattern 21.

### Third Embodiment of Power Converter

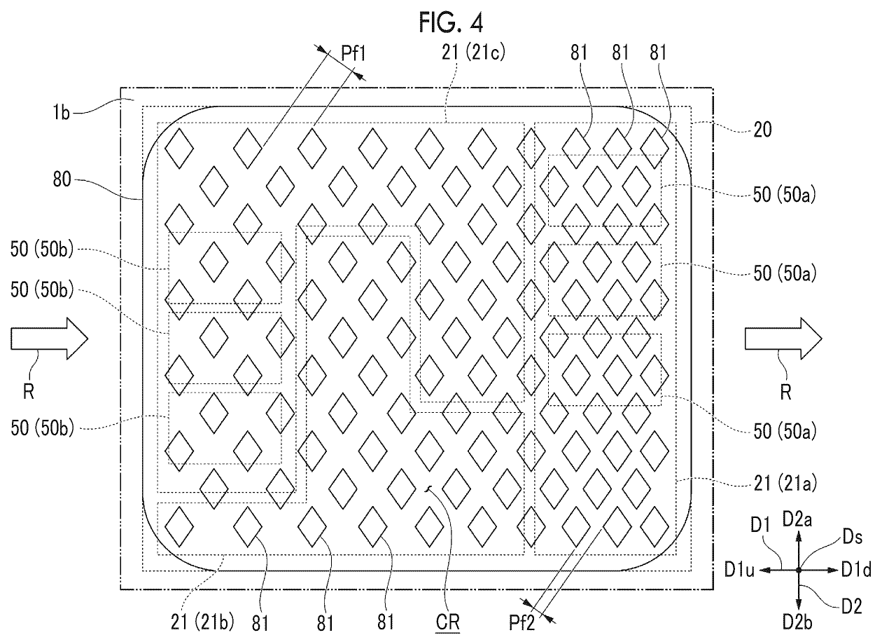

Next, a third embodiment of the power converter 100 will be described with reference to FIG. 4. In the third embodiment described below, the same reference numerals will be assigned to the configurations common to those in the first embodiment described above, and description thereof will be omitted. In the present embodiment, a configuration relating to the disposition of the fins 81 of the cooling parts 8 is partially different from the configuration relating to the disposition of the fins 81 of the cooling parts 8 described in the first embodiment.

The plurality of fins 81 protrude integrally with the base portion 80 toward the lower side Dsb from a surface facing the lower side Dsb of the pair of surfaces of the base portion 80, and are disposed at an interval from each other in a direction in which the base portion 80 extends. In the present embodiment, the interval (fin pitch) between the two adjacent fins 81 in the first direction D1 becomes narrower toward the downstream side D1d in the first direction D1 (for example, refer to Pf1 and Pf2 shown in FIG. 4). That is, the density of the fins 81 (the number of the fins 81 disposed per unit area on the surface facing the lower side Dsb of the base portion 80) of the surface facing the lower side Dsb of the base portion 80 increases toward the downstream side D1d. The fin 81 in the present embodiment is formed in a quadrangular column shape in which a cross section orthogonal to the lamination direction Ds has a rhombus shape.

### (Operational Effects)

The inventors have found that a flow velocity of the refrigerant flowing through the gap between the fins 81 increases as the interval between the fins 81 in the coolant flow path CR becomes narrower. In the above-described configuration, the interval between the fins 81 on the relatively downstream side D1d is narrower than the interval between the fins 81 on the relatively upstream side D1u. In this manner, the flow velocity of the liquid coolant R flowing through the coolant flow path CR in the first direction D1 increases toward the downstream side D1d. That is, the liquid coolant R flowing on the relatively downstream side D1d in the coolant flow path CR is more likely to transmit the cold energy to the fins 81, compared to when the intervals between the fins 81 in the first direction D1 are equal to each other. As a result, the power semiconductor element 50 included in the first element group 51 can be further cooled. Therefore, a decrease in cooling efficiency of the liquid coolant R can be suppressed.

### (Other Embodiments)

Hitherto, the embodiments of the present disclosure have been described in detail with reference to the drawings. However, specific configurations are not limited to the configurations of the embodiments, and additions, omissions, and substitutions of the configurations and other modifications can be made within the scope not departing from the concept of the present disclosure.

For example, the upstream side D1u and the downstream side D1d in the first direction D1 (flow direction of the liquid coolant R) described in the first embodiment are not limited to the above-described configuration, and may be reversely determined. That is, the liquid coolant R flowing into the coolant flow path CR from the refrigerant outlet may flow through the coolant flow path CR toward the upstream side D1u in the first direction D1, and may flow out from the coolant flow path CR through the refrigerant inlet 82a. In this case, the first element group 51 and the second element group 52 which are described in the first embodiment may be appropriately interchanged with each other.

In addition, a shape of the fin 81 described in the above-described embodiment is not limited to the quadrangular column shape in which the cross section orthogonal to the lamination direction Ds has a rhombus shape, and, for example, may be formed in a columnar shape in which the cross section orthogonal to the lamination direction Ds has a circular shape (or an elliptical shape). In addition, for example, the fins 81 may be formed in a flat plate shape integrally provided in the base portion 80 from the lower side Dsb, and may be aligned at an interval from each other in the first direction D1.

In addition, the refrigerant used in the cooling parts 8 is not limited to the liquid coolant R, and may be a refrigerant in a gaseous state.

In addition, in the above-described embodiment, the configuration of the power converter 100 of the 2-in-1 module has been described. However, the present disclosure is not limited to the 2-in-1 module, and, for example, a 6-in-1 module may be adopted.

In the above-described embodiment, the inverter has been described as an example of the power converter 100. However, the power converter 100 is not limited to the inverter. For example, the power converter 100 may be a converter or a combination of an inverter and a converter as long as a device causes the power semiconductor element 50 to perform power conversion. When the power converter 100 is the converter, a configuration may be adopted as follows. The alternating current is input to the second conductor 4 from an alternating current input power supply or the like (not shown) disposed outside the power converter 100. The power semiconductor element 50 electrically connected to the circuit pattern 21 converts the input alternating current into direct current, and direct current from the power semiconductor element 50 flows (is output) to the outside of the power converter 100 through the first conductor 3.

In addition, the configurations of the power converter 100 described in each embodiment are not limited to respectively independent configurations. The power converter 100 may be configured by appropriately combining the components described in each of the embodiments.

### Additional Notes

For example, the power converter 100 according to each of the embodiments is understood as follows.

(1) According to a first aspect, the power converter 100 includes the base plate 1 having the main surface 1a and the back surface 1b facing a side opposite to the main surface la, the circuit board 2 having the insulating plate 20 provided on the main surface la and the circuit pattern 21 formed on the insulating plate 20, the power conversion unit 5 having the first element group 51 and the second element group 52, each including the plurality of power semiconductor elements 50 electrically connected to the circuit pattern 21 and converting the input power, and the cooling parts 8 provided on the back surface 1b and transmitting the cold energy of the refrigerant (liquid coolant R) flowing in the first direction D1 inside the cooling parts 8 to the base plate 1. The first element group 51 is disposed to be separated from the second element group 52 on the downstream side D1d in the first direction D1. The plurality of power semiconductor elements 50 (first power semiconductor element 50a) included in the first element group 51 are aligned at an interval from each other in the second direction D2 intersecting with the first direction D1. The plurality of power semiconductor elements 50 (second power semiconductor element 50b) included in the second element group 52 are aligned at an interval from each other in the second direction D2. The interval between the two adjacent power semiconductor elements 50 in the first element group 51 is wider than the interval between the two adjacent power semiconductor elements 50 in the second element group 52.

In this manner, when the heat distribution in the second direction D2 of the refrigerant heated by the plurality of power semiconductor elements 50 included in the second element group 52 is considered, the heat removal of the plurality of power semiconductor elements 50 included in the first element group 51 is suppressed by the refrigerant having the relatively high temperature in the heat distribution. In other words, the probability increases in removing the heat of the plurality of power semiconductor elements 50 included in the first element group 51 by the refrigerant having the relatively low temperature in the heat distribution. Therefore, for example, compared to when the above-described interval in the first element group 51 is the same as the above-described interval in the second element group 52 (or is narrower than the interval in the second element group 52), the refrigerant flowing to the downstream side Did with respect to the second element group 52 inside the cooling parts 8 easily and effectively transmits the cold energy to the power semiconductor element 50 of the first element group 51.

(2) As the power converter 100 according to a second aspect, in the power converter 100 of the first aspect, the center position of the first element group 51 may be shifted to the one side D2a of both sides in the second direction D2 with respect to the center position of the second element group 52.

In this manner, the probability increases in removing the heat of the power semiconductor element 50 included in the first element group 51 by the relatively low-temperature refrigerant flowing in the first direction D1 on the one side D2a among the refrigerant flowing to the downstream side D1d of the second element group 52 inside the cooling parts 8.

(3) As the power converter 100 according to a third aspect, in the power converter 100 of the second aspect, the first element group 51 may include three or more power semiconductor elements 50. The interval between the two adjacent power semiconductor elements 50 in the first element group 51 may become narrower toward the one side D2a in the second direction D2.

In this manner, while the above-described operation is realized, it is possible to suppress an increase in the temperature difference between the plurality of power semiconductor elements 50 included in the first element group 51 cooled by the refrigerant. That is, it is possible to suppress concentration of the heat on some of the power semiconductor elements 50 included in the first element group 51.

(4) As the power converter 100 according to a fourth aspect, in the power converter 100 according to any one of the first to third aspects, the second element group 52 may include the same number of the power semiconductor elements 50 as the first element group 51. The plurality of power semiconductor elements 50 included in the second element group 52 may be disposed at an equal interval in the second direction D2.

In this manner, the above-described operation can be realized with higher accuracy.

(5) As the power converter 100 according to a fifth aspect, in the power converter 100 according to any one of the first to fourth aspects, the cooling parts 8 may include the base portion 80 coming into contact with the back surface 1b, and the plurality of fins 81 extending from the base portion 80 to a side opposite to the base plate 1 and coming into contact with the refrigerant. The plurality of fins 81 may be disposed at an interval from each other along the first direction D1 and the second direction D2. The interval between the two adjacent fins 81 may become narrower toward the downstream side D1d in the first direction D1.

In this manner, the flow velocity of the liquid coolant R flowing inside the cooling parts 8 in the first direction D1 increases toward the downstream side D1d in the first direction D1. Therefore, the liquid coolant R flowing on the relatively downstream side D1d inside the cooling parts 8 easily transmits the cold energy to the fins 81, compared to when the intervals between the fins 81 in the first direction D1 are equal to each other.

(6) According to a sixth aspect, the power converter 100 includes the base plate 1 having the main surface la and the back surface 1b facing a side opposite to the main surface 1a, the circuit board 2 having the insulating plate 20 provided on the main surface la and the circuit pattern 21 formed on the insulating plate 20, the power conversion unit 5 having the first power semiconductor element 50a and the second power semiconductor element 50b electrically connected to the circuit pattern 21 and converting the input power, and the cooling parts 8 provided on the back surface 1b and transmitting the cold energy of the refrigerant flowing in the first direction D1 inside the cooling parts 8 to the base plate 1. The first power semiconductor element 50a is disposed to be separated from the second power semiconductor element 50b on the downstream side D1d in the first direction D1. The cooling parts 8 include the base portion 80 coming into contact with the back surface 1b and the plurality of fins 81 extending from the base portion 80 to a side opposite to the base plate 1 and coming into contact with the refrigerant. The plurality of fins 81 are disposed at an interval from each other along the first direction D1 and the second direction D2 intersecting with the first direction D1. The interval between the two adjacent fins 81 becomes narrower toward the downstream side D1d in the first direction D1.

### INDUSTRIAL APPLICABILITY

According to the present disclosure, it is possible to provide a power converter capable of suppressing a decrease in cooling efficiency of a refrigerant.

### REFERENCE SIGNS LIST

1: base plate
1a: main surface
1b: back surface
2: circuit board
3: first conductor
3h, 4h: hole portion
4: second conductor
5: power conversion unit
6: bonding wire
7: resin case
8: cooling parts
20: insulating plate
20a: first surface
20b: second surface
21: circuit pattern
21a: first pattern
21b: second pattern
21c: third pattern
31: P bus bar
31a, 32a: terminal portion
31b, 32b: connecting portion
32: N bus bar
50: power semiconductor element
50a: first power semiconductor element
50b: second power semiconductor element
50e: side edge portion
51: first element group
52: second element group
80: base portion
81: fin
82: cooling case
82a: refrigerant inlet
100: power converter
CR: coolant flow path
D1: first direction
D1d: downstream side
D1u: upstream side
D2: second direction
D2a: one side
D2b: other side
Ds: lamination direction
Dsa: upper side
Dsb: lower side
P: potting space
R: liquid coolant

1. A power converter comprising:
a base plate having a main surface and a back surface facing a side opposite to the main surface;
a circuit board having an insulating plate provided on the main surface and a circuit pattern formed on the insulating plate;
a power conversion unit having a first element group and a second element group, each including a plurality of power semiconductor elements electrically connected to the circuit pattern and converting input power; and
cooling parts provided on the back surface and transmitting cold energy of a refrigerant flowing in a first direction inside the cooling parts to the base plate,
wherein the first element group is disposed to be separated from the second element group on a downstream side in the first direction,
the plurality of power semiconductor elements included in the first element group are aligned at an interval from each other in a second direction intersecting with the first direction,
the plurality of power semiconductor elements included in the second element group are aligned at an interval from each other in the second direction, and
an interval between two adjacent power semiconductor elements in the first element group is wider than an interval between two adjacent power semiconductor elements in the second element group.

2. The power converter according to claim 1,
wherein a center position of the first element group is shifted to one side of both sides in the second direction with respect to a center position of the second element group.

3. The power converter according to claim 2,
wherein the first element group includes three or more power semiconductor elements, and
the interval between the two adjacent power semiconductor elements in the first element group becomes narrower toward the one side in the second direction.

4. The power converter according to claim 1,
wherein the second element group includes the same number of the power semiconductor elements as the first element group, and
the plurality of power semiconductor elements included in the second element group are disposed at an equal interval in the second direction.

5. The power converter according to claim 1,
wherein the cooling parts include
a base portion coming into contact with the back surface, and
a plurality of fins extending from the base portion to a side opposite to the base plate and coming into contact with the refrigerant,
the plurality of fins are disposed at an interval from each other along the first direction and the second direction, and
an interval between two adjacent fins becomes narrower toward the downstream side in the first direction.

6. A power converter comprising:
a base plate having a main surface and a back surface facing a side opposite to the main surface;
a circuit board having an insulating plate provided on the main surface and a circuit pattern formed on the insulating plate;
a power conversion unit having a first power semiconductor element and a second power semiconductor element electrically connected to the circuit pattern and converting input power; and
cooling parts provided on the back surface and transmitting cold energy of a refrigerant flowing in a first direction inside the cooling parts to the base plate,
wherein the first power semiconductor element is disposed to be separated from the second power semiconductor element on a downstream side in the first direction,
the cooling parts include
a base portion coming into contact with the back surface, and
a plurality of fins extending from the base portion to a side opposite to the base plate and coming into contact with the refrigerant,
the plurality of fins are disposed at an interval from each other along the first direction and a second direction intersecting with the first direction, and
an interval between two adjacent fins becomes narrower toward the downstream side in the first direction.
